(19) United States
(12) Patent Application Publication
(10) Pub. No.: US 2018/0198093 A1
(43) Pub. Date: Jul. 12, 2018

(54) OLED DISPLAY PANEL AND MANUFACTURE METHOD THEREOF

(71) Applicant: Wuhan China Star Optoelectronics Technology Co., Ltd., Wuhan City (CN)

(72) Inventor: Wei Yu, Wuhan City (CN)

(21) Appl. No.: 15/505,102

(22) PCT Filed: Dec. 29, 2016
(86) PCT No.: PCT/CN2016/113052

§ 371 Date: Feb. 20, 2017

(30) Foreign Application Priority Data
Dec. 20, 2016 (CN) 201611185410.3

(51) Int. Cl. H01L 51/52; H01L 27/32; H01L 51/00; H01L 51/56

(52) U.S. Cl. CPC H01L 51/5281; H01L 27/3246; H01L 51/0097; H01L 51/5218; H01L 51/5234; H01L 2251/5338; H01L 51/56; H01L 51/0017; H01L 2227/323; H01L 2251/5315; H01L 51/5256

(57) ABSTRACT

The present invention provides an OLED display panel and a manufacture method thereof. In the manufacture method of the OLED display panel of the present invention, by using the method of plasma bombardment to make a surface of the inorganic layer in the thin film package layer corresponding to the areas of the non pixel areas have a diffuse reflection roughness so that the light emitted by the OLED light emitting layer of the each sub pixel will be diffused and reflected as being incident into the area. The light is divergent and is atomized everywhere, and cannot be intensively reflected and/or refracted, and then cannot outgo from the adjacent sub pixel. Therefore, it can prevent that the light emitted by each sub pixel interferes the adjacent sub pixels to raise the color purity of single sub pixel and to improve the color washout of the OLED display panel.

### FIELD OF THE INVENTION

The present invention relates to a display technology field, and more particularly to an OLED display panel and a manufacture method thereof.

### BACKGROUND OF THE INVENTION

The Organic Light Emitting Display (OLED) device possesses many outstanding properties of self-illumination, low driving voltage, high luminescence efficiency, short response time, high clarity and contrast, near 180° view angle, wide range of working temperature, applicability of flexible display and large scale full color display. The OLED is considered as the most potential display device.

The OLED can be categorized into two major types according to the driving methods, which are the Passive Matrix OLED (PMOLED) and the Active Matrix OLED (AMOLED), i.e. two types of the direct addressing and the Thin Film Transistor (TFT) matrix addressing. The AMOLED comprises pixels arranged in array and belongs to active display type, which has high lighting efficiency and is generally utilized for the large scale display devices of high resolution.

The OLED display element generally comprises a substrate, an anode located on the substrate, a Hole Injection Layer located on the anode, a Hole Transporting Layer located on the Hole Injection Layer, an emitting layer located on the Hole Transporting Layer, an Electron Transport Layer located on the emitting layer, an Electron Injection Layer located on the Electron Transport Layer and a Cathode located on the Electron Injection Layer. The principle of the OLED element is that the illumination generates due to the carrier injection and recombination under the electric field driving of the semiconductor material and the organic semiconductor illuminating material. Specifically, the Indium Tin Oxide (ITO) electrode and the metal electrode are respectively employed as the anode and the cathode of the Display. Under certain voltage driving, the Electron and the Hole are respectively injected into the Electron and Hole Transporting Layers from the cathode and the anode. The Electron and the Hole respectively migrate from the Electron and Hole Transporting Layers to the Emitting layer and bump into each other in the Emitting layer to form an exciton to excite the emitting molecule. The latter can illuminate after the radiative relaxation.

The flat panel display and lighting field on the basis of OLED has been widely concerned by scientific research and academic circle in the recent years. Particularly in these few years, the flexible OLED display panel with big future has already been risen in the world, and become the competition focus of all the panel makers.

The main stream manufacture method of the flexible OLED display panel is: the glass substrate is used to be the carrier, and a layer of polyimide (PI) film is coated on the entire surface of the glass substrate, and then the PI film is cured, and the PI film serves as the flexible substrate. Then, a water and oxygen barrier layer is manufactured on the cured PI film, and the thin film transistor layer, the OLED element layer and the TFE (Thin Film Encapsulation) layer are manufactured in order upward from the water and oxygen barrier layer. Thus, the flexible OLED display mother board is obtained. By cutting the flexible OLED display mother board, the respective flexible OLED display panels are manufactured.

As shown in FIG. 1, because the flexible OLED display panel will be frequently in a bent state, the phenomenon that a portion of light ultimately outgoes from the adjacent sub pixel occurs after the light emitted by the OLED light emitting layer 100 of one sub pixel is reflected and/or refracted in the package layer 200, and then interferes the outgoing light of the adjacent sub pixels, and leads to the color purity decrease of the single sub pixel, and the color washout issue appeared for the entire flexible OLED display panel to influence the display result.

### SUMMARY OF THE INVENTION

An objective of the present invention is to provide a manufacture method of an OLED display panel, which can prevent that the light emitted by each sub pixel interferes the adjacent sub pixels to raise the color purity of single sub pixel and to improve the color washout of the OLED display panel.

Another objective of the present invention is to provide an OLED display panel, which can prevent that the light emitted by each sub pixel interferes the adjacent sub pixels to raise the color purity of single sub pixel and to improve the color washout of the OLED display panel.

For realizing the aforesaid objectives, the present invention provides a manufacture method of an OLED display panel, comprising steps of:
step 1, providing a thin film transistor array substrate, and forming a plurality of anodes which are separately located on the thin film transistor array substrate;
step 2, forming a pixel definition layer on the plurality of anodes and the thin film transistor array substrate, and the pixel definition layer comprising a plurality of aperture areas which respectively correspond to the plurality of anodes and non aperture areas among the plurality of aperture areas;
step 3, respectively forming a plurality of OLED light emitting layers which are located on the plurality of anodes in the plurality of aperture areas of the pixel definition layer;
step 4, forming a cathode covering the plurality of OLED light emitting layers and the pixel definition layer with an entire surface on the plurality of OLED light emitting layers and the pixel definition layer;
step 5, forming a thin film package layer on the cathode, and the thin film package layer comprising a plurality of inorganic layers and organic layers which are stacked up and alternately located, wherein a surface at one side of each inorganic layer away from the OLED light emitting layer has a diffuse reflection roughness in areas corresponding to non aperture areas of the pixel definition layer.

In step 5, after forming each inorganic layer, a mask is used to implement plasma bombardment to each inorganic layer, and open pores corresponding to the non aperture areas of the pixel definition layer are configured on the mask, and a surface at one side of each inorganic layer away from the OLED light emitting layer forms a diffuse reflection roughness corresponding to an area of the open pores of the mask after the plasma bombardment.

The plasma is nitrogen trifluoride.

In the thin film package layer, both a structure layer contacting with the cathode and a structure layer at an outermost side are the inorganic layers.

The anode is a reflection electrode, and the cathode is a semi transparent electrode.

The present invention further provides an OLED display panel, comprising:
a thin film transistor array substrate;
a plurality of anodes which are separately located on the thin film transistor array substrate;
a pixel definition layer located on the plurality of anodes and the thin film transistor array substrate, and the pixel definition layer comprising a plurality of aperture areas which respectively correspond to the plurality of anodes and non aperture areas among the plurality of aperture areas;
a plurality of OLED light emitting layers which are respectively located on the plurality of anodes in the plurality of aperture areas of the pixel definition layer;
a cathode being located on the plurality of OLED light emitting layers and the pixel definition layer and covering the plurality of OLED light emitting layers and the pixel definition layer with an entire surface;
a thin film package layer being located on the cathode, and the thin film package layer comprising a plurality of inorganic layers and organic layers which are stacked up and alternately located, wherein a surface at one side of each inorganic layer away from the OLED light emitting layer has a diffuse reflection roughness in areas corresponding to non aperture areas of the pixel definition layer.

In the thin film package layer, a diffuse reflection roughness of a surface at one side of each inorganic layer away from the OLED light emitting layer in areas corresponding to non aperture areas of the pixel definition layer is obtained by plasma bombardment.

The plasma is nitrogen trifluoride.

In the thin film package layer, both a structure layer contacting with the cathode and a structure layer at an outermost side are the inorganic layers.

The anode is a reflection electrode, and the cathode is a semi transparent electrode.

The present invention further provides an OLED display panel, comprising:
a thin film transistor array substrate;
a plurality of anodes which are separately located on the thin film transistor array substrate;
a pixel definition layer located on the plurality of anodes and the thin film transistor array substrate, and the pixel definition layer comprising a plurality of aperture areas which respectively correspond to the plurality of anodes and non aperture areas among the plurality of aperture areas;
a plurality of OLED light emitting layers which are respectively located on the plurality of anodes in the plurality of aperture areas of the pixel definition layer;
a cathode being located on the plurality of OLED light emitting layers and the pixel definition layer and covering the plurality of OLED light emitting layers and the pixel definition layer with an entire surface;
a thin film package layer being located on the cathode, and the thin film package layer comprising a plurality of inorganic layers and organic layers which are stacked up and alternately located, wherein a surface at one side of each inorganic layer away from the OLED light emitting layer has a diffuse reflection roughness in areas corresponding to non aperture areas of the pixel definition layer;
wherein in the thin film package layer, both a structure layer contacting with the cathode and a structure layer at an outermost side are the inorganic layers;
wherein the anode is a reflection electrode, and the cathode is a semi transparent electrode.

The benefits of the present invention are: the present invention provides a manufacture method of an OLED display panel. By using the method of plasma bombardment to make a surface of the inorganic layer in the thin film package layer corresponding to the areas of the non pixel areas have a diffuse reflection roughness so that the light emitted by the OLED light emitting layer of the each sub pixel will be diffused and reflected as being incident into the area. The light is divergent and is atomized everywhere, and cannot be intensively reflected and/or refracted, and then cannot outgo from the adjacent sub pixel. Therefore, it can prevent that the light emitted by each sub pixel interferes the adjacent sub pixels to raise the color purity of single sub pixel and to improve the color washout of the OLED display panel. The present invention provides an OLED display panel. The surface of the inorganic layer in the thin film package layer corresponding to the non pixel areas has a diffuse reflection roughness in areas corresponding to non aperture areas of the pixel definition layer. It can prevent that the light emitted by each sub pixel interferes the adjacent sub pixels to raise the color purity of single sub pixel and to improve the color washout of the OLED display panel.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a diagram that a portion of the light emitted by OLED light emitting layer of one sub pixel in the flexible OLED display panel according to prior art outgoes from the adjacent sub pixel after the light is reflected and/or refracted in the package layer;

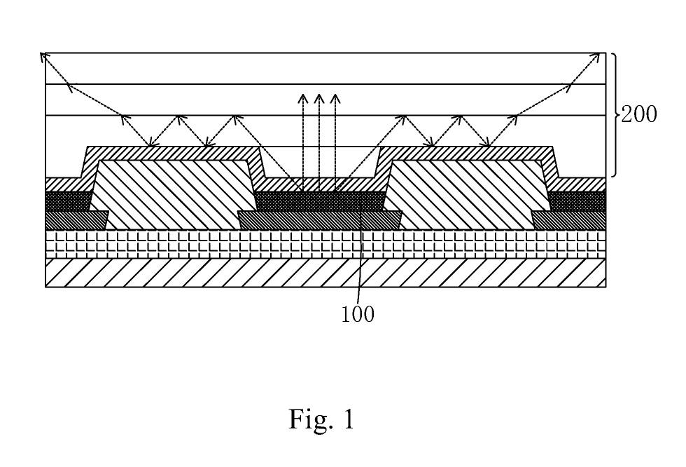

FIG. 2 is a flowchart of a manufacture method of an OLED display panel according to the present invention;

FIG. 3 is a diagram of step 1 of a manufacture method of an OLED display panel according to the present invention;

FIG. 4 is a diagram of step 2 of a manufacture method of an OLED display panel according to the present invention;

FIG. 5 is a diagram of step 3 of a manufacture method of an OLED display panel according to the present invention;

FIG. 6 is a diagram of step 4 of a manufacture method of an OLED display panel according to the present invention;

FIG. 7 is a diagram of step 5 of a manufacture method of an OLED display panel according to the present invention and a structure diagram of an OLED display panel according to the present invention;

FIG. 8 is a diagram that the mask is used to implement plasma bombardment to the inorganic layer in step 5 of the manufacture method of the OLED display panel of the present invention.

### DETAILED DESCRIPTION OF PREFERRED EMBODIMENTS

For better explaining the technical solution and the effect of the present invention, the present invention will be further described in detail with the accompanying drawings and the specific embodiments.

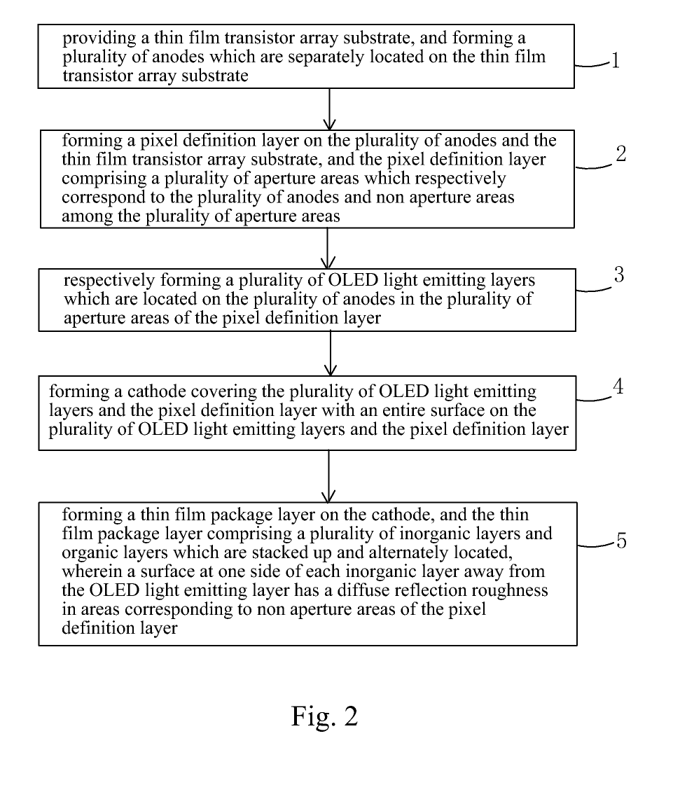

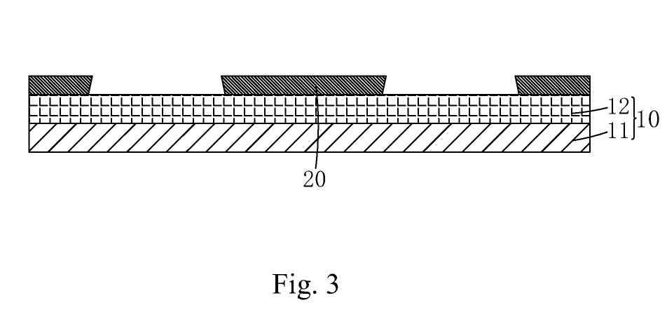

Please refer to FIG. 2. The present invention provides a manufacture method of an OLED display panel, comprising steps of:
step 1, as shown in FIG. 3, providing a thin film transistor array substrate 10, and forming a plurality of anodes 20 which are separately located on the thin film transistor array substrate 10.

Specifically, the thin film transistor array substrate 10 comprises a substrate 11 and a thin film transistor array layer 12 located on the substrate 11.

Specifically, the substrate 11 can be a rigid substrate or a flexible substrate. The rigid substrate is preferably to be a glass substrate, and the flexible substrate is preferably to be a polyimide layer.

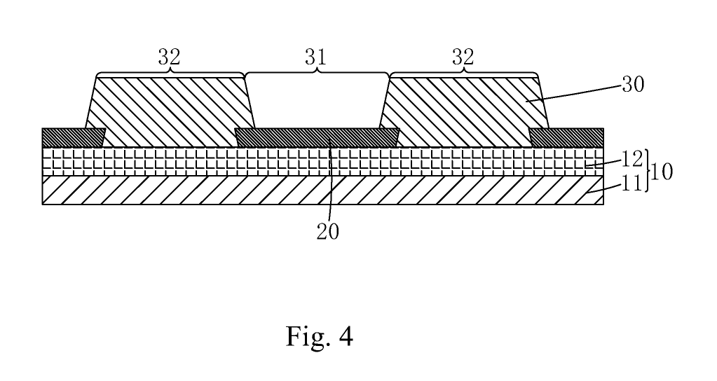

As the substrate 11 is a rigid substrate, the OLED display panel manufactured thereafter according to the present invention is a rigid OLED display panel. As the substrate 11 is a flexible substrate, the OLED display panel manufactured thereafter according to the present invention is a flexible OLED display panel.
step 2, as shown in FIG. 4, forming a pixel definition layer 30 on the plurality of anodes 20 and the thin film transistor array substrate 10, and the pixel definition layer 30 comprising a plurality of aperture areas 31 which respectively correspond to the plurality of anodes 20 and non aperture areas 32 among the plurality of aperture areas 31.

Specifically, the plurality of aperture areas 31 of the pixel definition layer 30 respectively correspond to the plurality of sub pixel areas of the OLED display panel, and the non aperture areas 32 of the pixel definition layer 30 correspond to the non sub pixel areas of the OLED display panel.

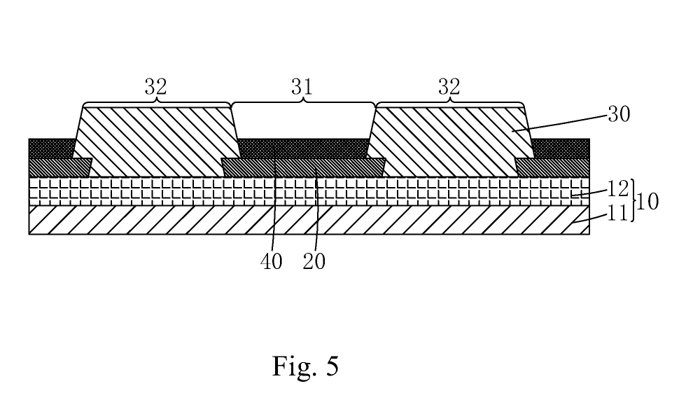

Specifically, a material of the pixel definition layer 30 is a transparent organic material.
step 3, as shown in FIG. 5, respectively forming a plurality of OLED light emitting layers 40 which are located on the plurality of anodes 20 in the plurality of aperture areas 31 of the pixel definition layer 30.

Specifically, in the step 5, the evaporation method is employed to form the plurality of OLED light emitting layers 40.

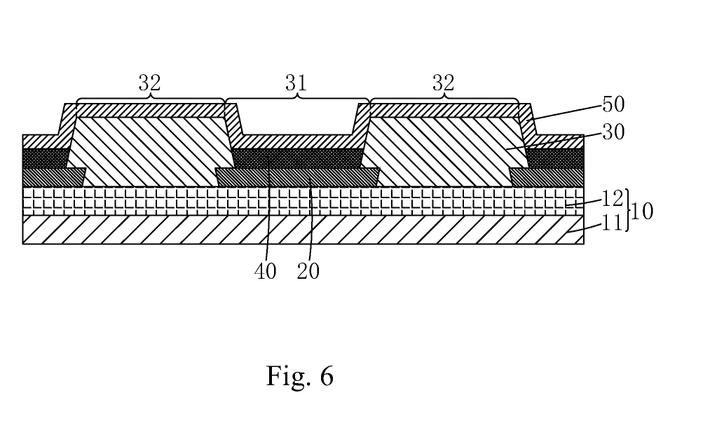

Specifically, the OLED light emitting layer 40 comprises a Hole Injection Layer (not shown), a Hole Transporting Layer (not shown), a light emitting layer (not shown), an Electron Transport Layer (not shown) and an Electron Injection Layer (not shown) stacking up on the anode 20 from bottom to top in order.
step 4, as shown in FIG. 6, forming a cathode 50 covering the plurality of OLED light emitting layers 40 and the pixel definition layer 30 with an entire surface on the plurality of OLED light emitting layers 40 and the pixel definition layer 30.

Specifically, the anode 20 is a reflection electrode and the cathode 50 is a semi transparent electrode so that the OLED display panel manufactured by the present invention constructs a top light emitting OLED display panel.

Preferably, the anode 20 comprises two Indium Tin Oxide (ITO) layers and a silver (Ag) layer sandwiched between the two Indium Tin Oxide layers.

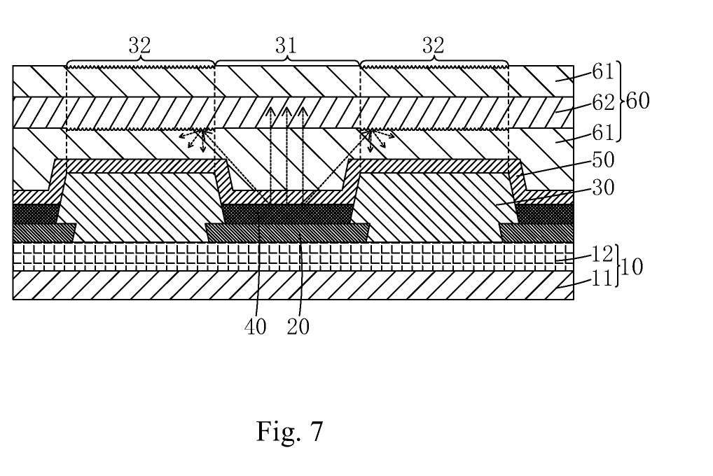

Specifically, a material of the cathode 50 is metal, and preferably is magnesium silver alloy.
step 5, as shown in FIG. 7, forming a thin film package layer 60 on the cathode 50, and the thin film package layer 60 comprising a plurality of inorganic layers 61 and organic layers 62 which are stacked up and alternately located, wherein a surface at one side of each inorganic layer 61 away from the OLED light emitting layer 40 has a diffuse reflection roughness in areas corresponding to non aperture areas 32 of the pixel definition layer 30.

After the light emitted by the OLED light emitting layer 40 of one sub pixel enters the thin film package layer 60, the diffuse reflection occurs in the area of each inorganic layer 61 having the diffuse reflection roughness. The light is divergent and is atomized everywhere, and cannot be intensively reflected and/or refracted, and then cannot outgo from the adjacent sub pixel. Therefore, it can prevent that the light emitted by each sub pixel interferes the adjacent sub pixels to raise the color purity of single sub pixel and to improve the color washout of the OLED display panel.

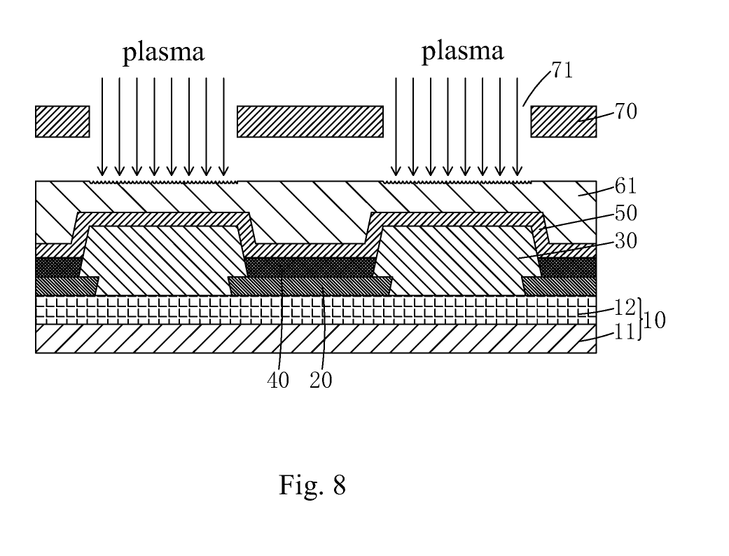

Specifically, as shown in FIG. 8, in step 5, after forming each inorganic layer 61, a mask 70 is used to implement plasma bombardment to each inorganic layer 61, and open pores 71 corresponding to the non aperture areas 32 of the pixel definition layer 30 are configured on the mask 70, and a surface at one side of each inorganic layer 61 away from the OLED light emitting layer 40 forms a diffuse reflection roughness corresponding to an area of the open pores 71 of the mask 70 after the plasma bombardment.

Preferably, the plasma is nitrogen trifluoride (NF3).

Preferably, in the thin film package layer 60, both a structure layer contacting with the cathode 50 and a structure layer at an outermost side are the inorganic layers 61.

As shown in FIG. 7, in one embodiment of the present invention, the thin film package layer 60 comprises two inorganic layers 61 and an inorganic layer 62 sandwiched between the two inorganic layers 61.

Specifically, the material of the inorganic layers 61 comprises at least one of silicon oxide (SiOx), silicon nitride (SiNx) and silicon oxynitride (SiOxNy); the material of the organic layers 62 comprises one or more of acrylic, HMDSO, polyhydroxy acrylics, polycarbonate and polystyrene.

Specifically, the thin film package layer 60 is used to stop the corrosion of the external water and oxygen to the OLED element to promote the usage life time of the OLED element.

In the aforesaid manufacture method of the OLED display panel, by using the method of plasma bombardment to make a surface of the inorganic layer 61 in the thin film package layer 60 corresponding to the areas of the non pixel areas have a diffuse reflection roughness so that the light emitted by the OLED light emitting layer 40 of the each sub pixel will be diffused and reflected as being incident into the area. The light is divergent and is atomized everywhere, and cannot be intensively reflected and/or refracted, and then cannot outgo from the adjacent sub pixel. Therefore, it can prevent that the light emitted by each sub pixel interferes the adjacent sub pixels to raise the color purity of single sub pixel and to improve the color washout of the OLED display panel.

Please refer to FIG. 7. Based on the aforesaid manufacture method of the OLED display panel, the present invention further provides an OLED display panel, comprising:
a thin film transistor array substrate 10;
a plurality of anodes 20 which are separately located on the thin film transistor array substrate 10;
a pixel definition layer 30 located on the plurality of anodes 20 and the thin film transistor array substrate 10, and the pixel definition layer 30 comprising a plurality of aperture areas 31 which respectively correspond to the plurality of anodes 20 and non aperture areas 32 among the plurality of aperture areas 31;
a plurality of OLED light emitting layers 40 which are respectively located on the plurality of anodes 20 in the plurality of aperture areas 31 of the pixel definition layer 30;
a cathode 50 covering the plurality of OLED light emitting layers 40 and the pixel definition layer 30 with an entire surface on the plurality of OLED light emitting layers 40 and the pixel definition layer 30;
a thin film package layer 60 located on the cathode 50, and the thin film package layer 60 comprising a plurality of inorganic layers 61 and organic layers 62 which are stacked up and alternately located, wherein a surface at one side of each inorganic layer 61 away from the OLED light emitting layer 40 has a diffuse reflection roughness in areas corresponding to non aperture areas 32 of the pixel definition layer 30.

Specifically, in the thin film package layer 60, a diffuse reflection roughness of a surface at one side of each inorganic layer 61 away from the OLED light emitting layer 40 in areas corresponding to non aperture areas 32 of the pixel definition layer 30 is obtained by plasma bombardment.

Specifically, the plasma is nitrogen trifluoride (NF3).

Preferably, in the thin film package layer 60, both a structure layer contacting with the cathode 50 and a structure layer at an outermost side are the inorganic layers 61.

As shown in FIG. 7, in one embodiment of the present invention, the thin film package layer 60 comprises two inorganic layers 61 and an inorganic layer 62 sandwiched between the two inorganic layers 61.

Specifically, the material of the inorganic layers 61 comprises at least one of silicon oxide (SiOx), silicon nitride (SiNx) and silicon oxynitride (SiOxNy); the material of the organic layers 62 comprises one or more of acrylic, HMDSO, polyhydroxy acrylics, polycarbonate and polystyrene.

Specifically, the thin film transistor array substrate 10 comprises a substrate 11 and a thin film transistor array layer 12 located on the substrate 11.

Specifically, the substrate 11 can be a rigid substrate or a flexible substrate. The rigid substrate is preferably to be a glass substrate, and the flexible substrate is preferably to be a polyimide layer.

Specifically, a material of the pixel definition layer 30 is a transparent organic material.

Specifically, the OLED light emitting layer 40 comprises a Hole Injection Layer (not shown), a Hole Transporting Layer (not shown), a light emitting layer (not shown), an Electron Transport Layer (not shown) and an Electron Injection Layer (not shown) stacking up on the anode 20 from bottom to top in order.

Specifically, the anode 20 is a reflection electrode and the cathode 50 is a semi transparent electrode so that the OLED display panel of the present invention constructs a top light emitting OLED display panel.

Preferably, the anode 20 comprises two Indium Tin Oxide (ITO) layers and a silver (Ag) layer sandwiched between the two Indium Tin Oxide layers.

Specifically, a material of the cathode 50 is metal, and preferably is magnesium silver alloy.

In the aforesaid OLED display panel, a surface of the inorganic layer 61 in the thin film package layer 60 corresponding to the areas of the non pixel areas has a diffuse reflection roughness so that the light emitted by the OLED light emitting layer 40 of the each sub pixel will be diffused and reflected as being incident into the area. The light is divergent and is atomized everywhere, and cannot be intensively reflected and/or refracted, and then cannot outgo from the adjacent sub pixel. Therefore, it can prevent that the light emitted by each sub pixel interferes the adjacent sub pixels to raise the color purity of single sub pixel and to improve the color washout of the OLED display panel.

In conclusion, the present invention provides an OLED display panel and a manufacture method thereof. In the manufacture method of the OLED display panel of the present invention, by using the method of plasma bombardment to make a surface of the inorganic layer in the thin film package layer corresponding to the areas of the non pixel areas have a diffuse reflection roughness so that the light emitted by the OLED light emitting layer of the each sub pixel will be diffused and reflected as being incident into the area. The light is divergent and is atomized everywhere, and cannot be intensively reflected and/or refracted, and then cannot outgo from the adjacent sub pixel. Therefore, it can prevent that the light emitted by each sub pixel interferes the adjacent sub pixels to raise the color purity of single sub pixel and to improve the color washout of the OLED display panel. In the OLED display panel of the present invention, the surface of the inorganic layer in the thin film package layer corresponding to the non pixel areas has a diffuse reflection roughness in areas corresponding to non aperture areas of the pixel definition layer. It can prevent that the light emitted by each sub pixel interferes the adjacent sub pixels to raise the color purity of single sub pixel and to improve the color washout of the OLED display panel.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacture method of an OLED display panel, comprising steps of:
step 1, providing a thin film transistor array substrate, and forming a plurality of anodes which are separately located on the thin film transistor array substrate;
step 2, forming a pixel definition layer on the plurality of anodes and the thin film transistor array substrate, and the pixel definition layer comprising a plurality of aperture areas which respectively correspond to the plurality of anodes and non aperture areas among the plurality of aperture areas;
step 3, respectively forming a plurality of OLED light emitting layers which are located on the plurality of anodes in the plurality of aperture areas of the pixel definition layer;
step 4, forming a cathode covering the plurality of OLED light emitting layers and the pixel definition layer with an entire surface on the plurality of OLED light emitting layers and the pixel definition layer;
step 5, forming a thin film package layer on the cathode, and the thin film package layer comprising a plurality of inorganic layers and organic layers which are stacked up and alternately located, wherein a surface at one side of each inorganic layer away from the OLED light emitting layer has a diffuse reflection roughness in areas corresponding to non aperture areas of the pixel definition layer.

2. The manufacture method of the OLED display panel according to claim 1, wherein in step 5, after forming each inorganic layer, a mask is used to implement plasma bombardment to each inorganic layer, and open pores corresponding to the non aperture areas of the pixel definition layer are configured on the mask, and a surface at one side of each inorganic layer away from the OLED light emitting layer forms a diffuse reflection roughness corresponding to an area of the open pores of the mask after the plasma bombardment.

3. The manufacture method of the OLED display panel according to claim 2, wherein the plasma is nitrogen trifluoride.

4. The manufacture method of the OLED display panel according to claim 1, wherein in the thin film package layer, both a structure layer contacting with the cathode and a structure layer at an outermost side are the inorganic layers.

5. The manufacture method of the OLED display panel according to claim 1, wherein the anode is a reflection electrode, and the cathode is a semi transparent electrode.

6. An OLED display panel, comprising:
a thin film transistor array substrate;
a plurality of anodes which are separately located on the thin film transistor array substrate;
a pixel definition layer located on the plurality of anodes and the thin film transistor array substrate, and the pixel definition layer comprising a plurality of aperture areas which respectively correspond to the plurality of anodes and non aperture areas among the plurality of aperture areas;
a plurality of OLED light emitting layers which are respectively located on the plurality of anodes in the plurality of aperture areas of the pixel definition layer;
a cathode being located on the plurality of OLED light emitting layers and the pixel definition layer and covering the plurality of OLED light emitting layers and the pixel definition layer with an entire surface;
a thin film package layer being located on the cathode, and the thin film package layer comprising a plurality of inorganic layers and organic layers which are stacked up and alternately located, wherein a surface at one side of each inorganic layer away from the OLED light emitting layer has a diffuse reflection roughness in areas corresponding to non aperture areas of the pixel definition layer.

7. The OLED display panel according to claim 6, wherein in the thin film package layer, a diffuse reflection roughness of a surface at one side of each inorganic layer away from the OLED light emitting layer in areas corresponding to non aperture areas of the pixel definition layer is obtained by plasma bombardment.

8. The OLED display panel according to claim 7, wherein the plasma is nitrogen trifluoride.

9. The OLED display panel according to claim 6, wherein in the thin film package layer, both a structure layer contacting with the cathode and a structure layer at an outermost side are the inorganic layers.

10. The OLED display panel according to claim 6, wherein the anode is a reflection electrode, and the cathode is a semi transparent electrode.

11. An OLED display panel, comprising:
a thin film transistor array substrate;
a plurality of anodes which are separately located on the thin film transistor array substrate;
a pixel definition layer located on the plurality of anodes and the thin film transistor array substrate, and the pixel definition layer comprising a plurality of aperture areas which respectively correspond to the plurality of anodes and non aperture areas among the plurality of aperture areas;
a plurality of OLED light emitting layers which are respectively located on the plurality of anodes in the plurality of aperture areas of the pixel definition layer;
a cathode being located on the plurality of OLED light emitting layers and the pixel definition layer and covering the plurality of OLED light emitting layers and the pixel definition layer with an entire surface;
a thin film package layer being located on the cathode, and the thin film package layer comprising a plurality of inorganic layers and organic layers which are stacked up and alternately located, wherein a surface at one side of each inorganic layer away from the OLED light emitting layer has a diffuse reflection roughness in areas corresponding to non aperture areas of the pixel definition layer;
wherein in the thin film package layer, both a structure layer contacting with the cathode and a structure layer at an outermost side are the inorganic layers;
wherein the anode is a reflection electrode, and the cathode is a semi transparent electrode.

12. The OLED display panel according to claim 11, wherein in the thin film package layer, a diffuse reflection roughness of a surface at one side of each inorganic layer away from the OLED light emitting layer in areas corresponding to non aperture areas of the pixel definition layer is obtained by plasma bombardment.

13. The OLED display panel according to claim 12, wherein the plasma is nitrogen trifluoride.
